(19) United States
(12) Patent Application Publication
(10) Pub. No.: US 2026/0114126 A1
(43) Pub. Date: Apr. 23, 2026

(54) TRANSISTOR AND DISPLAY DEVICE INCLUDING THE SAME

(71) Applicant: LG Display Co., Ltd., Seoul (KR)

(72) Inventors: Jong Ho KIM, Paju-si (KR); Jung Yul YANG, Paju-si (KR)

(73) Assignee: LG Display Co., Ltd., Seoul (KR)

(21) Appl. No.: 19/314,767

(22) Filed: Aug. 29, 2025

(30) Foreign Application Priority Data
Oct. 18, 2024 (KR) 10-2024-0143232

(51) Int. Cl. H10K 59/121; H10D 86/40; H10D 86/60; H10K 59/131

(52) U.S. Cl. CPC H10K 59/1213; H10D 86/423; H10D 86/441; H10D 86/60; H10K 59/131

(57) ABSTRACT

Disclosed is a transistor and a display device including the same, the transistor including an oxide semiconductor layer with a first source-drain region, a channel, and a second source-drain region arranged in a first direction. An upper gate electrode is disposed above the oxide semiconductor layer, overlapping the channel with a gate insulating film interposed. A lower gate electrode is disposed below the oxide semiconductor layer, overlapping at least the channel, and is electrically connected to the upper gate electrode at a location extending outward from the oxide semiconductor layer. The transistor further includes a first source-drain electrode and a second source-drain electrode connected to the first and second source-drain regions, respectively. A voltage supply line is connected to the lower gate electrode and is configured to supply a positive constant voltage. This structure enables threshold voltage control without additional fabrication steps.

### CROSS-REFERENCE TO RELATED APPLICATION(S)

This application claims the benefit of Korean Patent Application No. 10-2024-0143232, filed on Oct. 18, 2024, which is hereby incorporated by reference as if fully set forth herein.

### BACKGROUND

### Technical Field

The present disclosure relates to a transistor, and more particularly, to a transistor capable of easily controlling a threshold voltage and a display device including the same.

### Description of the Related Art

Display devices that display images in TVs, monitors, smartphones, tablet PCs, laptops, etc., are being used in various ways and forms.

A display device includes a plurality of pixels to implement images and has transistors to control the operation of each pixel. In addition, transistors formed in the same process as the transistors provided in the pixels are also provided in a non-active area around the plurality of pixels.

Among display devices, in order to implement device compactness and clear color display, light emitting display devices that have light-emitting elements within a display panel without a separate light source are being considered as competitive applications.

Transistors provided in a display device for various functions of the display device require different characteristics, and thus require differences in configuration.

### BRIEF SUMMARY

The disclosure describes a transistor structure that includes both upper and lower gate electrodes to enable precise control of the threshold voltage in transistors used in display devices. By supplying a bias voltage to the lower gate, the threshold voltage of transistors, particularly those with short and wide channels used for driving currents, can be adjusted to be similar to that of switching transistors with different geometries. This configuration allows for tailored electrical performance without requiring additional fabrication steps or different material layers, thereby reducing power consumption and operational stress.

The approach uses a common oxide semiconductor layer and allows the lower gate to share existing circuit lines, which simplifies the manufacturing process. The ability to control the threshold voltage through a reference voltage line supports a range of transistor functions within each pixel, such as switching, driving, and sensing, contributing to improved display performance, energy efficiency, and long-term reliability.

For example, various embodiments of the present disclosure is directed to a transistor and a display device including the same that substantially obviate one or more problems due to limitations and disadvantages of the related art.

An aspect of the present disclosure is to enable selective adjustment of the threshold voltages of transistors.

Another aspect of the present disclosure is to minimize the threshold voltage of each transistor by compensating the threshold voltage of a transistor having a high threshold voltage to be similar to the threshold voltage of a transistor having a low threshold voltage by supplying a reference voltage even if transistors with different channel widths and lengths have different characteristics.

Another aspect of the present disclosure is to enable reduction in stress and reduction in power consumption of transistors without affecting the characteristics of the transistors by selectively compensating the threshold voltages of the transistors.

Another aspect of the present disclosure is to implement transistors having different characteristics without any additional processes. Therefore, the yet another aspect of the present disclosure is to provide a display device that is capable of reducing greenhouse gases generated by additional manufacturing processes and implementing process optimization.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

To achieve these aspects and other advantages and in accordance with the purpose of the disclosure, as embodied and broadly described herein, a transistor includes an oxide semiconductor layer having a first source-drain region, a channel, and a second source-drain region in a first direction, an upper gate electrode disposed above the oxide semiconductor layer and configured to overlap the channel with a gate insulating film interposed therebetween, a lower gate electrode disposed below the oxide semiconductor layer, configured to overlap at least the channel, and connected to the upper gate electrode at a position configured to extend outwardly from the oxide semiconductor layer, a first source-drain electrode and a second source-drain electrode connected to the first and second source-drain regions, respectively, and a voltage supply line connected to the lower gate electrode and configured such that a positive constant voltage is supplied to the voltage supply line.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic plan view showing a display device according to one embodiment of the present disclosure;

FIG. 2 is a circuit diagram showing a subpixel according to one embodiment of the present disclosure;

FIG. 3 is a plan view showing a transistor according to one embodiment of the present disclosure;

FIG. 4 is a cross-sectional view taken along lines I-I′ and II-II′ of FIG. 3;

FIG. 5 is a graph showing I-V characteristic changes depending on a positive bias voltage applied to a lower gate electrode of the transistor according to one embodiment of the present disclosure;

FIG. 6 is a circuit diagram showing a subpixel according to one embodiment of the present disclosure;

FIG. 7 is a plan view showing first and second transistors of FIGS. 2 or 6;

FIG. 8 is a cross-sectional view taken along line III-III′ of FIG. 7;

FIG. 9 is a graph showing I-V characteristics of the first and second transistors of the present disclosure;

FIG. 10 is a graph showing threshold voltage and on current changes according to a change in a voltage difference (Vgs) between a gate electrode and a source electrode of a transistor; and

FIG. 11 is a cross-sectional view showing the display device according to one embodiment of the present disclosure.

### DETAILED DESCRIPTION

Hereinafter, exemplary embodiments of the present disclosure will be described with reference to the accompanying drawings.

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on,” “above,” “under” and “next to,” at least one intervening element can be present between the two elements, unless “immediate(ly)” or “direct(ly)” or “close(ly) is used. It will be understood that when an element or layer is referred to as being “connected to,” or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

In describing the various example embodiments of the present disclosure, terms such as “first” and “second” can be used to describe a variety of components. These terms aim to distinguish the same or similar components from one another and do not limit the components.

Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

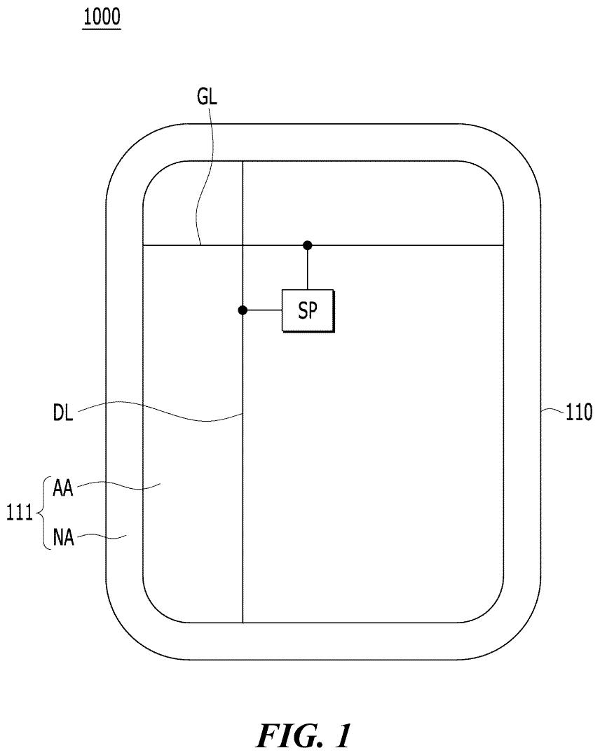

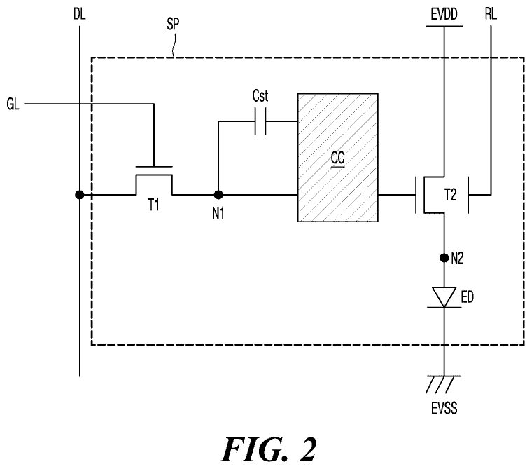

FIG. 1 is a schematic plan view showing a display device according to one embodiment of the present disclosure. FIG. 2 is a circuit diagram showing a subpixel according to one embodiment of the present disclosure.

Referring to FIGS. 1 and 2, a display device 1000 according to one embodiment of the present disclosure may include a display panel 110, and a case (not shown) that accommodates the side surfaces of the display panel 110 and the lower portion of the display panel 110. A non-active area NA of the display panel 110 may be covered by the case or by a separate light-shielding film.

A printed circuit film and/or a battery may be provided between the lower portion of the display panel 110 and the case.

The display panel 110 may include a substrate 111 including an active area AA and the non-active area NA surrounding the active area AA, and a driver connected to the substrate 111. The driver may be integrated with the configuration of an array provided in the active area AA within the substrate 111, may be connected to the substrate 111 in a Chip On Glass (COG) manner, or may be connected to a printed circuit board through a film or connector in a Chip On Film (COF) manner on the substrate 111. Alternatively, the driver may include both a configuration integrated into the substrate 111 and a configuration outside the COG or COF.

The active area AA is an area where an image is displayed. A plurality of subpixels SP is disposed in the active area AA of the display panel 110, and an image may be displayed using the plurality of subpixels SP. An area other than the active area AA may serve as the non-active area NA.

The non-active area NA may be disposed in an edge area surrounding the active area AA where an image is displayed. At least one driver for driving the plurality of subpixels SP may be disposed in the non-active area NA. The driver may include a Gate-In-Panel (GIP). The Gate-In-Panel (GIP) may be connected to a plurality of gate lines GL of the active area AA and sequentially supply gate voltage signals to the plurality of gate lines GL.

Various additional components for driving the subpixels SP in the active area AA may be further disposed in the non-active area NA.

At least one subpixel SP among the plurality of pixels SP may include a first transistor T1, a second transistor T2, a storage capacitor Cst, a compensation circuit CC, and a light-emitting element ED, as shown in FIG. 2.

For example, the first transistor T1 may be a switching transistor, and the second transistor T2 may be a driving transistor. The first transistor T1 and/or the second transistor T2 may be provided at each of a plurality of subpixels provided on the substrate 111.

A first electrode (e.g., a drain electrode) of the first transistor T1 is conductively connected to a data line DL, and a second electrode (e.g., a source electrode) of the first transistor T1 is conductively connected to a first node N1. A gate electrode of the first transistor T1 is conductively connected to the gate line GL. The first transistor T1 transmits a data signal supplied through the data line DL to the first node N1 in response to a scan signal supplied through the gate line GL.

The storage capacitor Cst is conductively connected to the first node N1 and charges the first node N1 with an applied voltage. When the subpixel SP does not have a compensation circuit CC, the first node N1 may be connected to a first gate electrode of the second transistor T2.

The first electrode (e.g., a drain electrode) of the second transistor T2 receives a high-potential driving voltage EVDD, and a second electrode (e.g., a source electrode) of the second transistor T2 is conductively connected to a first electrode (e.g., the anode) of the light-emitting element ED at a second node N2. A second electrode (e.g., the cathode) may receive a low-potential driving voltage EVSS. The second transistor T2 may control the amount of a driving current Ids flowing to the light-emitting element ED depending on a voltage difference Vgs between a gate electrode and the source electrode.

As shown in FIG. 2, gate electrodes of the second transistor T2 may include a first gate electrode connected to the compensation circuit CC or the first node N1 and a second gate electrode connected to a reference voltage line RL. The second transistor T2 may further include the second gate electrode to adjust a threshold voltage Vth. For example, when a positive bias voltage is applied to the second gate electrode through the reference voltage line RL, the threshold voltage may be adjusted to be lowered to a more negative value. The positive bias voltage means a positive constant voltage, which is a positive voltage of a constant value. When the positive bias voltage is selectively applied to the second gate electrode through the reference voltage line RL, the threshold voltage may be lowered compared to when a single gate voltage is applied through the first gate electrode. A reference voltage in a positive constant voltage state may be supplied through the reference voltage line RL. The reference voltage line RL may be connected to a gate or one electrode (source) of a buffer transistor or a sensing transistor to control the gate or the electrode.

As another example, when a negative bias voltage is applied to the second gate electrode of the second transistor T2 through the reference voltage line RL, the threshold voltage may be adjusted to be raised to a more positive value.

Among the transistors provided in the subpixel SP, the switching transistor requires high-speed driving for fast switching operation and may also require high current output. The driving transistor enables gradation expression in a section from an initial gate voltage Vgsᵢₙₜ at which a current value for a gate voltage applied to the gate electrode changes to a gate voltage reaching a saturation state that reaches a sufficient current. The gate voltage that reaches the saturation state of the transistor may be referred to as the threshold voltage Vth. For example, the driving transistor that supplies a driving current to the light-emitting element ED, such as the second transistor T2 of FIG. 2, must secure a section (Vgsᵢₙₜ-Vth) from the initial gate voltage Vgsᵢₙₜ to the threshold voltage Vth from the off state to the saturation state in an I-V curve for gradation expression to a certain extent or more. In addition, in some cases, even the driving transistor may require high current output for high luminance expression of the light-emitting element ED under the area of the subpixel minimized due to integration. For this purpose, a channel width of a semiconductor layer of the driving transistor may be larger than a channel width of a semiconductor layer of the switching transistor, and a channel length of the semiconductor layer of the driving transistor may be smaller than a channel length of the semiconductor layer of the switching transistor. Accordingly, the driving transistor may secure a certain section in which the current changes in the section in which the voltage changes from the initial gate voltage to the threshold voltage, thereby enabling rich gradation expression. In addition, when the switching transistor capable of enabling high-speed switching operation and the driving transistor capable of enabling gradation expression respectively include a semiconductor layer formed of the same material, at least one of the widths and lengths of the channels of these transistors may be set to be different and the slopes of the curves of the I-V curves thereof may be set to be different, but a positive bias voltage may be applied through the lower gate electrode of the driving transistor to adjust the threshold voltage of the driving transistor with a small slope to the level of the low threshold voltage of the switching transistor. Accordingly, the driving transistor may have a small slope of the I-V curve by adjusting the width/length of the channel, and at the same time, may have a low threshold voltage by applying the positive bias voltage to the lower gate electrode.

Further, because the driving transistor is a transistor that supplies a driving current to the light-emitting element ED, a large amount of current must flow through the driving transistor, and for this purpose, the driving transistor requires a large channel width. In this case, if the section from the off state to the saturation state in the I-V curve of the driving transistor for gradation expression is secured to a certain extent or more, the difference between the initial gate voltage Vgsᵢₙₜ and the threshold voltage Vth becomes large. That is, if the initial gate voltage Vgsᵢₙₜ of the driving transistor is set to a level similar to that of the switching transistor, the threshold voltage of the driving transistor is high. When the threshold voltage of the driving transistor increases, the driving voltage may increase and thus cause an increase in power consumption for driving the subpixel, and at the same time, a stress level applied to the driving transistor itself may increase and thus act as a deterioration factor of the driving transistor. Accordingly, the driving transistor is required to lower the threshold voltage Vth while maintaining the slope of the I-V curve. The driving transistor of the present disclosure has the second gate electrode connected to the reference voltage line RL in addition to the first gate electrode configured to supply the gate voltage, so that the gate voltage may be selectively supplied through the second gate electrode to shift the high threshold voltage in the negative direction, thereby being capable of lowering the driving voltage, reducing the power consumption, and exhibiting a stress reduction effect. This may improve the reliability of the driving transistor and secure robustness of the driving transistor so that the driving transistor does not deteriorate even after long-term driving.

The switching transistor is a transistor provided in the subpixel to control switching of the subpixel. Since the switching transistor is involved in high-speed operation, a channel size of the switching transistor may be smaller than that of the driving transistor. However, in the longitudinal direction of the channel, an effective channel length change ΔL may occur due to diffusion during the conducting process or doping process of the source and drain regions of the semiconductor layer. Particularly, when the channel width decreases, the effective channel length change ΔL may also become more severe. The channel size of the switching transistor for high-resolution and high-speed operation is small, and when the effective channel length is reduced due to the conducting process or the doping process, the threshold voltage may be very low and thus cause a leakage current in the off state, and in severe cases, the switching transistor may not be in a stable off state. In addition, the switching transistor tends to have an increased dispersion in the decrease in the threshold voltage when the semiconductor layer has high mobility. Therefore, the switching transistor needs to have a high threshold voltage for operation stability.

In this way, the driving transistor and the switching transistor described above require different channel widths and lengths due to different operating characteristics, and have threshold voltages with opposite tendencies. It is difficult to adjust the opposite tendencies of the threshold voltages of the driving transistor and the switching transistor by only adjusting the widths and lengths of the channels. In addition to the first gate electrode, the transistor according to one embodiment of the present disclosure has the second gate electrode to which a gate voltage is selectively supplied, thereby adjusting the threshold voltage of the transistor, and thus being capable of adjusting the threshold voltages of the switching transistor and the driving transistor to match or be similar.

The semiconductor layer of the first transistor T1 and/or the semiconductor layer of the second transistor T2 may include amorphous silicon (a-Si), crystalline silicon, such as polycrystalline silicon (poly-Si) or low-temperature polycrystalline silicon (poly-Si), or an oxide semiconductor.

If the first transistor T1 and/or the second transistor T2 includes an oxide semiconductor, the oxide semiconductor has a small or almost no leakage current when turned off, and may thus obtain stable characteristics during operation.

The transistors according to one embodiment of the present disclosure may have different characteristics by varying the widths and lengths of the channels thereof, and at least the second transistor T2 included in the subpixel may further include the second gate electrode connected to the reference voltage line RL. In this case, the first transistor T1 in the subpixel may include a single gate electrode. The second gate electrode and the first gate electrode may be located below and above the oxide semiconductor layer.

In a display device according to another embodiment of the present disclosure, transistors have semiconductor layers formed of an oxide semiconductor manufactured in the same process, a transistor having a single gate electrode may be disposed in a non-active area surrounding subpixels, and a transistor further including a second gate electrode connected to the above-described reference voltage line may be disposed as a transistor that supplies a driving current in each subpixel. Since the transistors having different characteristics may have the oxide semiconductor layers manufactured in the same process, additional processes required for manufacturing the transistors of different stacks depending on the characteristics, such as providing a plurality of metal layers and interlayer insulating films between the plurality of metal layers, may be omitted. In addition, among the transistors, a transistor having a low slope of an I-V curve, for example, a driving transistor, may be provided with the second gate electrode connected to a separate power supply voltage line or the reference voltage line, thereby being capable of lowering the threshold voltage of the transistor. In this case, the slope of the I-V curve may be maintained to enable gradation expression, and the threshold voltage may be lowered to prevent an increase in power consumption and an increase in stress on the transistor.

The first and second transistors T1 and T2 include the same oxide semiconductor layer, and at least one of the channel width andr channel length provided in the center of the oxide semiconductor layer may be changed to vary I-V curve characteristics.

For example, the channel length of the first transistor T1 may be long and the channel width of the first transistor T1 may be short. The first transistor T1 functions as a switching transistor that controls the signal from the second transistor T2 that functions as a driving transistor within the subpixel SP. Therefore, the first transistor T1 may be integrated at a high resolution so that the channel width and channel length thereof may be set to process limits. In addition, the first transistor T1 may be designed so that the channel length thereof is relatively long compared to the channel width thereof in order to prepare for occurrence of a channel length change ΔL (a distance between the edge of the gate electrode and the edge of the channel) in the channel length direction.

The second transistor T2 may have a shorter channel length and a longer channel width compared to the first transistor T1. Because the second transistor T2 supplies a current to the light-emitting element ED and a large amount of current may flow for high luminance expression, the channel width of the second transistor T2 is increased to prepare for this.

The channel length may be determined as a distance between source-drain regions on both sides of each transistor. The channel width may be determined in a direction that overlaps the gate electrode of each transistor and intersects the channel length.

The second transistor T2 may supply a large amount of driving current to the light-emitting element ED by increasing the channel width. The second transistor T2 may have an I-V curve that may express gradation by adjusting the channel width and length. The second transistor T2 according to one embodiment of the present disclosure has a the second gate electrode located below the oxide semiconductor layer in addition to the first gate electrode located above the oxide semiconductor layer, the second gate electrode is connected to the power supply voltage line, and a positive bias voltage is applied to the second gate electrode to adjust the threshold voltage in the negative direction, so that the threshold voltage of the second transistor T2 may be adjusted to a level similar to that of the first transistor T1. The initial gate voltage Vgsᵢₙₜ at which a current value for a gate voltage changes when a single gate electrode is provided is approximately 0 V, and therefore, the second transistor T2 having a small slope of the I-V curve may have a higher threshold voltage than the first transistor T1, but the second transistor T2 according to one embodiment of the present disclosure additionally may have a lower gate electrode connected to the reference voltage line RL or a voltage supply line to which a power voltage is selectively applied, enable application of a back bias voltage, and shift the I-V curve in the negative direction. Therefore, the second transistor T2 according to one embodiment of the present disclosure may lower the threshold voltage, and also reduce power consumption. In addition, stress applied to the second transistor T2 may also be alleviated.

Unlike the second transistor T2, the first transistor T1 may not have a lower gate electrode. In another example, the first transistor T1 may have a lower gate electrode, which is connected to a line that supplies a different voltage from the power supply voltage line connected to the second transistor T2, and adjust a threshold voltage, etc., differently from the second transistor T2.

A display device according to another embodiment of the present disclosure may shift a threshold voltage in the positive direction by applying a negative bias voltage as a gate voltage applied to the lower gate electrode of any one of transistors provided on a substrate.

Further, a display device according to another embodiment of the present disclosure may apply a transistor having gate electrodes above and below an oxide semiconductor layer to a region other than subpixels so as to adjust a threshold voltage. The region other than the subpixels may be, for example, a non-active area of the substrate, and more specifically, a gate-in-panel within the non-active area.

In the display device according to one embodiment of the present disclosure, each of the plurality of subpixels may further include a third transistor including a semiconductor layer including a third channel having a different width from the second channel, and the third transistor may have different characteristics from the first and second transistors T1 and T2.

The transistors and display devices according to the embodiments of the present disclosure includes the oxide semiconductor layer in at least one of the transistors formed on the substrate 111, thereby being capable of having excellent off characteristics, being formed at a relatively low temperature compared to other materials, maintaining amorphous characteristics, and having high mobility.

The light-emitting element ED outputs light corresponding to the driving current. The light-emitting element ED may output light corresponding to any one color among red, green, blue, and white.

The light-emitting element ED may include an anode, an intermediate layer disposed on the anode, and a cathode that supplies a common voltage. The intermediate layer may include at least one emission layer and, when an electric field is formed between the anode and the cathode, may be implemented to emit light of the same color for each subpixel SP, such as white light, or may be implemented to emit light of different colors for each subpixel SP, such as red, green, or blue light. The intermediate layer may include various types of common layers and functional layers in addition to the emission layer to efficiently supply holes and electrons to the emission layer.

The light-emitting element ED may be a top emission-type diode or a bottom emission-type diode.

The compensation circuit CC may be additionally provided in the subpixel SP to compensate the threshold voltage of the second transistor T2, etc. In some cases, the compensation circuit CC may be omitted. The compensation circuit CC may be formed of one or more transistors. The compensation circuit CC may include one or more transistors and capacitors, and may be configured in various ways depending on a compensation method. The subpixel SP including the compensation circuit CC may include circuits of various structures having different numbers of transistors and/or capacitors, such as 3T1C, 4T2C, 5T2C, 6T1C, 6T2C, 7T1C, and 7T2C.

The Gate-In-Panel (GIP) may be included in the non-active area NA. The gate-in-panel outputs gate signals to the gate lines GL depending on, for example, a gate control signal input from a timing controller. The gate-in-panel (GIP) may include a plurality of transistors, and the plurality of transistors may be formed in the same process as the transistors of the subpixels SP.

In addition, the transistors included in the gate-in-panel may include transistors having an oxide semiconductor layer as an active layer and transistors having a semiconductor layer formed of crystalline silicon as an active layer.

Hereinafter, a transistor according to one embodiment of the present disclosure will be described.

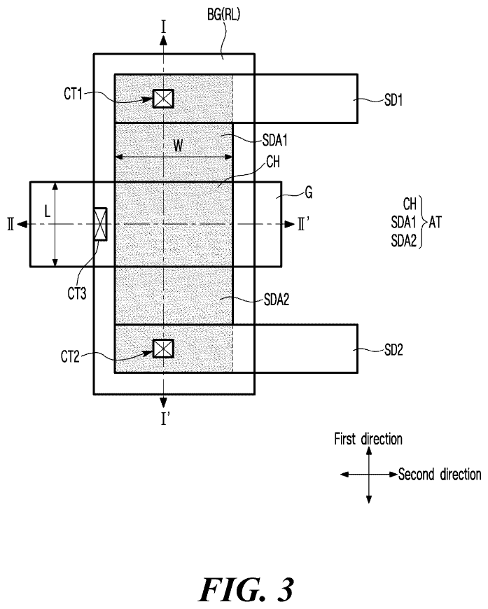

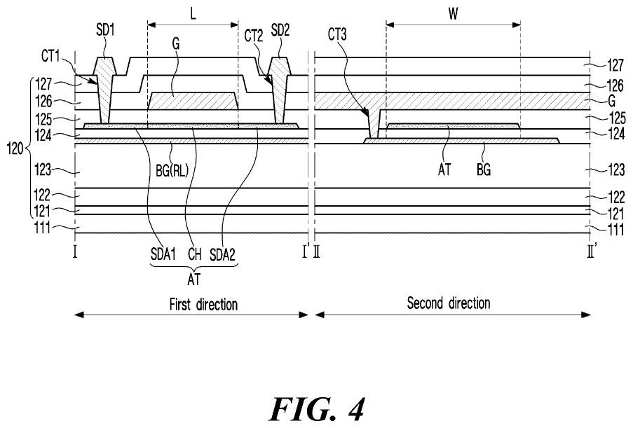

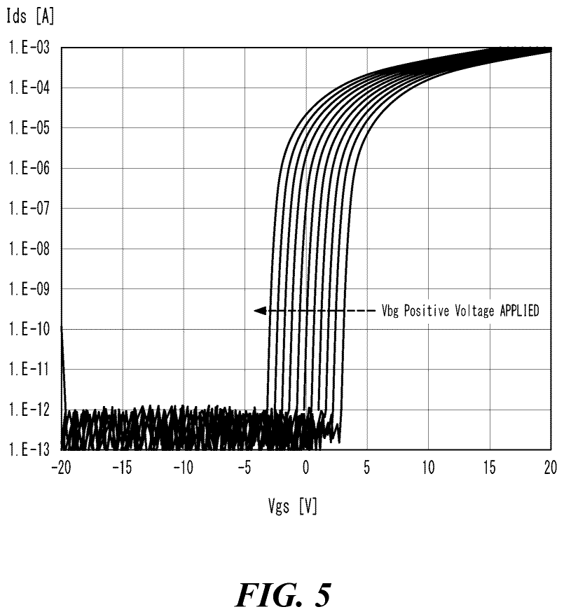

FIG. 3 is a plan view showing the transistor according to one embodiment of the present disclosure, FIG. 4 is a cross-sectional view taken along lines I-I′ and II-II′ of FIG. 3, and FIG. 5 is a graph showing I-V characteristic changes depending on a positive bias voltage applied to a lower gate electrode of the transistor according to one embodiment of the present disclosure.

As shown in FIGS. 3 and 4, the transistor according to one embodiment of the present disclosure may include an oxide semiconductor layer AT having a first source-drain region SDA1, a channel CH, and a second source-drain region SDA2 in a first direction, an upper gate electrode G disposed above the oxide semiconductor layer AT and configured to overlap the channel CH with a gate insulating film 125 interposed therebetween, a lower gate electrode BG disposed below the oxide semiconductor layer AT, configured to overlap at least the channel CH, and connected to the upper gate electrode G at a position extending outwardly from the oxide semiconductor layer AT, and a voltage supply line connected to a first source-drain electrode SD1 and a second source-drain electrode SD2 respectively connected to the first and second source-drain regions SDA1 and SDA2 and the lower gate electrode BG and configured such that a positive bias voltage or a constant voltage is supplied to the voltage supply line.

The lower gate electrode BG and the voltage supply line may be disposed to be integrated with each other.

Here, the voltage supply line may be the reference voltage line RL. The voltage supply line may use one of voltage lines disposed in the subpixels without forming an additional line.

In some cases, the voltage supply line may be formed as a separate line and connected to the lower gate electrode BG.

The lower gate electrode BG may have a width that is greater than at least the width W of the channel CH, and may be connected to the upper gate electrode G through a third contact hole CT3 at a position deviating from the oxide semiconductor layer AT. The upper gate electrode G and the lower gate electrode BG are connected at a position that does not overlap the oxide semiconductor layer AT. At least one interlayer insulating film may be provided between the oxide semiconductor layer AT and the lower gate electrode BG. The third contact hole CT3 may be configured to penetrate the gate insulating film and the at least one interlayer insulating film. The third contact hole CT3 may be spaced apart from the oxide semiconductor layer AT.

The channel CH of the oxide semiconductor layer AT has a length L between the first and second source-drain regions SDA1 and SDA2 in the first direction and a width W in a second direction intersecting the first direction.

As shown in FIGS. 3 and 4, the voltage supply line may be the reference voltage line RL. The reference voltage line RL may be connected to, for example, source and drain electrodes of a sensing transistor included in the compensation circuit. When the reference voltage line RL supplies a voltage to the lower gate electrode BG, the voltage may be supplied to the lower gate electrode BG of the transistor through a circuit configuration included in the subpixel without adding a separate voltage line, thereby being capable of implementing process optimization.

The reference voltage line RL may be provided to be integrated with the lower gate electrode BG, as shown in FIG. 4. In this case, the reference voltage line RL may be located in a layer below the oxide semiconductor layer AT. Therefore, in the transistor according to one embodiment of the present disclosure, the lower gate electrode of the transistor may receive a positive bias voltage or a positive constant voltage through a conductive connection between the reference voltage line connected to one transistor included in the subpixel and the lower gate electrode BG without adding a separate voltage supply line.

The transistor according to one embodiment of the present disclosure may be provided in each subpixel of the substrate 111.

The substrate 111 may be formed of a flexible plastic material and may have flexibility. The substrate 111 may include polyimide, and may include a thin glass material having flexibility.

The substrate 111 may include a support substrate, such as polyethylene terephthalate (PET), and a polyimide film, independently. The substrate 110 may include an adhesive film, such as a pressure sensitive adhesive (PSA) film, to adhere the polyimide film to the PET support substrate. The substrate 111 may have a structure in which two organic films are stacked with an inorganic interlayer film (not shown) interposed therebetween.

A plurality of insulating films 120: 121, 122, 123, 124, 125, 126, and 127 is stacked on the active area AA and the non-active area NA of the substrate 111 so as to insulate electrodes of the transistor from each other.

A first insulating film 121 is disposed on the active area AA and the non-active area NA on the substrate 111. The first insulating film 121 may be called a buffer film and may perform the same function as buffer films known in the technical field. The first insulating film 121 may be disposed on the substrate 111 so as to protect structures on the substrate 111 that are vulnerable to moisture from moisture penetrating through the substrate 111, and may planarize the surface of the substrate 111.

The first insulating film 121 may be disposed up to the edge of the substrate 111 to prevent moisture from penetrating from the edge of the substrate 111. The first insulating film 121 may be a single inorganic film or may include a plurality of inorganic films that are alternately stacked.

For example, the first insulating film 121 may include at least one inorganic film of a silicon oxide (SiOₓ) film, a silicon nitride (SiNₓ) film, and a silicon oxynitride (SiOₓN_{y}) film, or may include, for example, a multilayer film in which the above-described inorganic films are stacked.

A second insulating film 122 may be disposed on the first insulating film 121. The second insulating film 122 may function as a second buffer layer, and may also serve as a gate insulating film of the transistors (not shown) that constitute a gate driver (not shown) disposed in the non-active area NA.

The second insulating film 122 may include an inorganic film, for example, a silicon oxide (SiOₓ) film, a silicon nitride (SiNₓ) film, or a multilayer film thereof.

A third insulating film 123 may be disposed on the second insulating film 122. The third insulating film 123 may also function as an interlayer insulating film of the transistors (not shown) that constitute the gate driver (not shown) disposed in the non-active area NA.

The third insulating film 123 may include an inorganic material. The inorganic material may be, for example, a silicon nitride (SiNₓ) film.

The lower gate electrode BG may be provided on the third insulating film 123.

The lower gate electrode BG may be formed of a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The lower gate electrode BG may have a multilayer film structure including at least two conductive metal materials.

The lower gate electrode BG and the reference voltage line RL may be provided together on the third insulating film 123. The reference voltage line RL may be integrated with the lower gate electrode BG.

A fourth insulating film 124 may be disposed on the third insulating film 123 provided with the lower gate electrode BG. The fourth insulating film 124 may function as a buffer layer. The fourth insulating film 124 may include the oxide semiconductor layer AT disposed thereon to serve to planarize the upper surface of the substrate 111 to form the base of the transistor.

The fourth insulating film 124 may include an inorganic material. The inorganic material may include, for example, a silicon oxide (SiOₓ) film or a multilayer film in which inorganic films are stacked.

If the fourth insulating film 124 includes a silicon oxide film, hydrogen particles are not emitted during a heat treatment process during the manufacturing process, so that reduction in the reliability of the oxide semiconductor layer AT disposed adjacent to the fourth insulating film 124 due to hydrogen particles may be prevented.

The oxide semiconductor layer AT may be disposed on the fourth insulating film 124.

The oxide semiconductor layer AT include the channel CH that overlaps the upper gate electrode G, and the first source-drain region SDA1 and the second source-drain region SDA2 connected to the first and second source-drain electrodes SD1 and SD2.

The channel CH may be a region of the oxide semiconductor layer AT overlapping the upper gate electrode G, i.e., a region to which carriers move. The channel CH may not be doped with impurities.

In the oxide semiconductor layer AT, the first source-drain region SDA1 and the second source-drain region SDA2 may be regions excluding the channel CH, i.e., regions to which the first source-drain electrode SD1 and the second source-drain electrode SD2 are connected to have conductivity. The first source-drain region SDA1 and the second source-drain region SDA2 may be disposed on both sides of the channel CH with the channel interposed therebetween.

The first source-drain region SDA1 and the second source-drain region SDA2 may include conducting parts that are doped with impurities or the like. In some cases, the first source-drain region SDA1 and the second source-drain region SDA2 may include regions where a conducting region, into which impurities are injected, and a non-conducting region, into which impurities are not injected, coexist. For example, the non-conducting region may be disposed between the conducting region and the channel CH.

The oxide semiconductor layer AT includes an oxide semiconductor material. The oxide semiconductor material may be formed of an oxide of a metal, such as zinc (Zn), indium (In), gallium (Ga), tin (Sn), or titanium (Ti), or a combination of a metal, such as zinc (Zn), indium (In), gallium (Ga), tin (Sn), or titanium (Ti), and an oxide thereof.

More specifically, the oxide semiconductor material of the oxide semiconductor layer AT may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), or the like.

Since the oxide semiconductor layer AT of the transistor includes the oxide semiconductor material, an off current is low and an effect of blocking a leakage current is improved, thereby reducing power consumption.

A fifth insulating film 125 may be disposed on the oxide semiconductor layer AT.

Since an active layer of the oxide semiconductor layer AT is disposed on the fourth insulating film 124 in a patterned form, the fifth insulating film 125 is disposed to cover the upper surface and side surfaces of the active layer of the oxide semiconductor layer AT.

Since the fifth insulating film 125 is disposed to cover the oxide semiconductor layer AT including the oxide semiconductor material, the fifth insulating film 125 may be formed of an inorganic material that does not include hydrogen particles. For example, the fifth insulating film 125 may include a silicon oxide (SiOₓ) film or a multilayer film in which inorganic films are stacked. The fifth insulating film 125 may function as a gate insulating film.

The upper gate electrode G may be disposed on the fifth insulating film 125. The upper gate electrode G may serve to turn on or turn off the second transistor T2 in response to a signal from the compensation circuit CC or the capacitor Cst shown in FIG. 2. The upper gate electrode G is insulated from the oxide semiconductor layer AT by the fifth insulating film 125, and is disposed to overlap at least a portion of the oxide semiconductor layer AT to form the channel CH in the oxide semiconductor layer AT. Here, the channel length L may be determined by the upper gate electrode G overlapping the oxide semiconductor layer AT in the first direction, and the channel width W may be determined by the upper gate electrode G overlapping the oxide semiconductor layer AT in the second direction.

The upper gate electrode G may be formed of a conductive metal material.

Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The upper gate electrode G may have a multilayer film structure including at least two conductive metal materials.

A sixth insulating film 126 and a seventh insulating film 127 may be disposed on the upper gate electrode G.

The sixth insulating film 126 covers the upper and side portions of the upper gate electrode G to insulate the first source-drain electrode SD1 and the second source-drain electrode SD2 from the upper gate electrode G.

The sixth insulating film 126 may be a single inorganic film or may be formed as a plurality of inorganic films that is stacked. As the inorganic film, one or more inorganic materials may be selected from a silicon oxide (SiOₓ) film, a silicon nitride (SiNₓ) film, and a silicon oxynitride (SiOₓN_{y}) film.

The seventh insulating film 127 disposed on the sixth insulating film 126 may be disposed to planarize the upper portion of the second transistor T2 including a pattern shape, such as the oxide semiconductor layer AT or the gate electrode G.

The seventh insulating film 127 may be formed of an organic material, an inorganic material, or a stack of an organic film and an inorganic film.

The first source-drain electrode SD1 and the second source-drain electrode SD2 may be disposed on the seventh insulating film 127. The first source-drain electrode SD1 and the second source-drain electrode SD2 may be arranged to be spaced apart from each other with the upper gate electrode G interposed therebetween. At this time, the first source-drain electrode SD1 and the second source-drain electrode SD2, and the upper gate electrode G may be disposed in different layers, as described above.

The first source-drain electrode SD1 and the second source-drain electrode SD2 may be formed of a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The first source-drain electrode SD1 and the second source-drain electrode SD2 may have a multilayer film structure including at least two conductive metal materials.

Each of the first source-drain electrode SD1 and the second source-drain electrode SD2 is connected to the oxide semiconductor layer AT. The first source-drain electrode SD1 is connected to the first source-drain region SDA1 of the oxide semiconductor layer AT through a first contact hole CT1 provided in the fifth to seventh insulating films 125, 126, and 127, and the second source-drain electrode SD2 is connected to the second source-drain region SDA2 of the oxide semiconductor layer AT through a second contact hole CT2 provided in the fifth to seventh insulating films 125, 126, and 127.

FIGS. 3 and 4 show an example in which the lower gate electrode BG is connected to the upper gate electrode G overlapping the lower gate electrode BG through the third contact hole CT3 provided in the fourth and fifth insulating films 124 and 125 at a portion protruding from a plane of the oxide semiconductor layer AT. Here, the lower gate electrode BG may be integrated with the reference voltage line RL, and the upper gate electrode G and the lower gate electrode BG may be at the same potential as the voltage supplied to the reference voltage line RL. Here, the voltage supplied to the reference voltage line RL is a positive bias voltage, and the positive bias voltage value may vary depending on the size of the threshold voltage to be adjusted.

For example, the reference voltage line RL may extend in the first direction from the lower gate electrode BG. The extending reference voltage line RL may be connected to a sensing transistor or a buffer transistor in the compensation circuit CC.

In some cases, a positive constant voltage may be supplied to the lower gate electrode BG through a line to which a rated voltage is applied, separately from the reference voltage line RL.

When the transistor is turned on, the reference voltage Vref or the power supply voltage may be selectively supplied through the lower gate electrode BG, and the positive constant voltage may also be supplied to the upper gate electrode G through the connection between the lower gate electrode BG and the upper gate electrode G through the third contact hole CT3.

The transistor shown in FIGS. 3 and 4, for example, when applied as a driving transistor, may have a wide channel width W and a short channel length L, and may secure a certain section (Vgsint-Vth) of a gate voltage in the range from the initial gate voltage Vgsint at which the current value for the gate voltage applied to the gate electrode changes to the threshold voltage Vth reaching the saturation state that reaches a sufficient current. However, the transistor including both the upper gate electrode G and the lower gate electrode BG according to one embodiment of the present disclosure is not limited to the driving transistor. The transistor having the above-described structure may be applied to any transistor requiring adjustment of a threshold voltage.

In addition, the transistor of the present disclosure may have the upper gate electrode G and the lower gate electrode BG to solve an increase in the threshold voltage Vth when a gate voltage is supplied by a single gate electrode, and may adjust the threshold voltage Vth through the lower gate electrode BG in the case in which among transistors provided on the substrate, a transistor includes an oxide semiconductor layer having a characteristic difference. As shown in FIG. 5, as the magnitude of the positive bias voltage Vbg applied to the lower gate electrode BG gradually increases, the I-V curve gradually shifts in the negative direction. This means that, as the magnitude of the positive bias voltage applied through the lower gate electrode of the transistor increases, the threshold voltage of the transistor decreases.

For example, when the transistor of FIGS. 3 and 4 is provided as a driving transistor, a certain section in which the current changes may be secured in the section in which the voltage changes from the initial gate voltage to the threshold voltage, thereby enabling rich gradation expression. In addition, when the switching transistor capable of high-speed switching operation and the driving transistor capable of gradation expression are provided to include the semiconductor layer of the same material, the widths/lengths of the channels of these transistors may be set to be different and the slopes of the curves of the I-V curves may be set to be different, but a positive bias voltage may be applied through the lower gate electrode of the driving transistor to adjust the threshold voltage of the driving transistor with a small slope to the level of the low threshold voltage of the switching transistor. Accordingly, the driving transistor may have a small slope of the I-V curve by adjusting the width/length of the channel and, at the same time, may have a low threshold voltage by applying the positive bias voltage to the lower gate electrode.

According to another embodiment of the present disclosure, when the transistor of FIGS. 3 and 4 is provided as a switching transistor, the threshold voltage of the transistor may be adjusted to increase by applying a negative bias voltage to the lower gate electrode BG.

Hereinafter, a subpixel having a different circuit structure from FIG. 2 will be described.

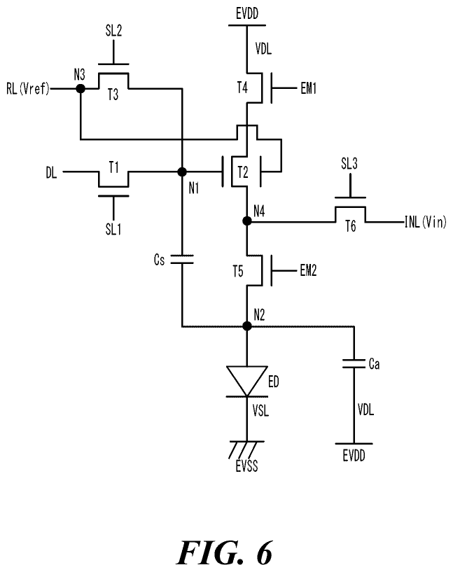

FIG. 6 is a circuit diagram showing a subpixel according to one embodiment of the present disclosure.

As shown in FIG. 6, a subpixel SP according to one embodiment of the present disclosure includes first to sixth transistors T1, T2, T3, T4, T5, and T6, a first capacitor Cs, a second capacitor Ca, and a light-emitting element ED.

Each of the first to sixth transistors T1, T2, T3, T4, T5, and T6 may independently be a p-type transistor or an n-type transistor. FIG. 6 illustrates an example in which the first to sixth transistors T1, T2, T3, T4, T5, and T6 are n-type transistors.

Each of the first to sixth transistors T1, T2, T3, T4, T5, and T6 is turned on when a high voltage is applied to a gate electrode. The first transistor T1 may be connected to a data line DL and function as a switching transistor that supplies data. The second transistor T2 may be connected to the first transistor T1 and function as a driving transistor, and the sixth transistor T6 may function as an initialization transistor. The third transistor T3 may be connected to a reference voltage line RL and supply a reference voltage to one side of the first capacitor Cst. The fourth and fifth transistors T4 and T5 may be connected to first and second emission control lines EM1 and EM2, respectively, to adjust supply of a driving current.

A gate electrode of the first transistor T1 is connected to a first gate line SL1, a first electrode (e.g., a drain electrode) of the first transistor T1 is connected to the data line DL, and a second electrode (e.g., a source electrode) of the first transistor T1 is connected to a first electrode of the first capacitor Cs and a gate electrode of the second transistor T2 at a first node N1.

The first electrode of the first capacitor Cs is connected to the first node N1 and a second electrode of the first capacitor Cs is connected to a second node N2.

An upper gate electrode of the second transistor T2 is connected to the second electrode of the first transistor T1 at the first node N1, and the second transistor T2 is disposed between the fourth transistor T4 and the fifth transistor T5. A first electrode of the second transistor T2 is connected to the fourth transistor T4 to which a high-potential driving voltage EVDD is supplied, and a second electrode of the second transistor T2 is connected to a first electrode of the fifth transistor T5 at a fourth node N4. The second transistor T2 further includes a lower gate electrode, and the lower gate electrode may be conductively connected to the reference voltage line RL at a third node N3.

A gate electrode of the third transistor T3 is connected to a second gate line SL2, a first electrode (e.g., a drain electrode) of the third transistor T3 is connected to the reference voltage line RL, and the second electrode (e.g., a source electrode) of the third transistor T3 is connected to one electrode of the first capacitor Cs and the gate electrode of the second transistor T2 at the first node N1. Here, the first electrode of the third transistor T3 is conductively connected to the lower gate electrode of the second transistor T2 through the third node N3.

Gate electrodes of the fourth transistor T4 and the fifth transistor T5 are connected to the first and second emission control lines EM1 and EM2, respectively.

A first electrode of the fourth transistor T4 is connected to a first power supply voltage line VDL to which the high-potential driving voltage EVDD is supplied, and a second electrode of the fourth transistor T4 is connected to the first electrode of the second transistor T2.

A first electrode of the fifth transistor T5 is connected to the second electrode of the second transistor T2 at the fourth node N4, and a second electrode of the fifth transistor T5 may be connected to a first electrode of the light-emitting element ED at the second node N2.

In addition, a gate electrode of the sixth transistor T6 is connected to a third gate line SL3, a first electrode of the sixth transistor T6 is connected to an initialization line INL to which an initialization voltage Vin is supplied, and a second electrode of the sixth transistor T6 is connected to the first electrode of the fifth transistor T5 through the fourth node N4.

In addition, the second capacitor Ca is provided between the second node N2 and the first power supply voltage line VDL.

The light-emitting element ED is provided between the second node N2 and a second power supply voltage line VSL. A low-potential driving voltage EVSS is supplied through the second power supply voltage line VSL.

The circuit operation of FIG. 6 will be described as follows.

When a first or second gate signal is selectively applied to the gate electrode of the first transistor T1 or the third transistor T3 through the first gate line SL1 or the second gate line SL2, a data signal supplied through the first transistor T1 or a reference voltage signal Vref supplied through the third transistor T3 is applied to the first electrode of the first capacitor Cs through the first node N1.

The second transistor T2 supplies a driving current flowing between the fourth and fifth transistors T4 and T5 to the first electrode of the light-emitting element ED through the second node N2 depending on emission control signals applied to the first and second emission control lines EM1 and EM2. The lower gate electrode of the second transistor T2 is connected to the reference voltage line RL through the third node N3, so that the reference voltage Vref is selectively supplied to the lower gate electrode of the second transistor T2 through the reference voltage line RL, and when a positive bias voltage is applied as the reference voltage Vref, the threshold voltage of the second transistor T2 may be lowered.

The fourth transistor T4 may supply a voltage proportional to the high-potential driving voltage EVDD to the first electrode of the second transistor T2 by the emission control signal supplied by the first emission control line EM1.

In addition, when a third gate signal is supplied to the gate electrode of the sixth transistor T6 through the third gate line SL3, a voltage proportional to an initialization voltage Vin transmitted to the initialization line INL may be transmitted to the first electrode of the fifth transistor T5 through the fourth node N4.

The fifth transistor T5 may transmit a signal proportional to the high-potential driving voltage EVDD or a signal proportional to the initialization voltage Vin to the second node N2 through the fourth node N4 depending on the light emission control signal supplied to the second light emission control line EM2, and accordingly, the light-emitting element ED may be driven.

The second capacitor Ca is an auxiliary capacitor, and is connected to the first power supply voltage line VDL to which the high-potential driving voltage EVDD is applied, thereby maintaining the potential of the second node N2 above the low-potential driving voltage EVSS.

Thereby, when the initialization voltage Vin is applied to the first electrode of the light-emitting element ED, the light-emitting element ED is initialized, or when a signal proportional to the high-potential driving voltage EVDD is applied to the first electrode of the light-emitting element ED, the light-emitting element ED emits light while a current flows in the direction of the second power supply voltage line VSL. In one embodiment of the present disclosure, the low-potential driving voltage EVSS supplied to the second power supply voltage line VSL may be set to be lower than the high-potential driving voltage EVDD supplied to the first power supply voltage line VDL.

Each of light-emitting elements ED may display one color among white, red, green, and blue.

In the display device according to one embodiment of the present disclosure, for example, the second transistor T2 may be formed to have the configuration of the above-described transistor including the lower gate electrode shown in FIGS. 3 and 4.

The first and third to sixth transistors T1, T3, T4, T5, and T6 may be configured as transistors that do not have a lower gate electrode, or may be configured such that at least one of the first, and third to sixth transistors T1, T3, T4, T5, and T6 has a lower gate electrode but has different threshold voltage control from the second transistor T2.

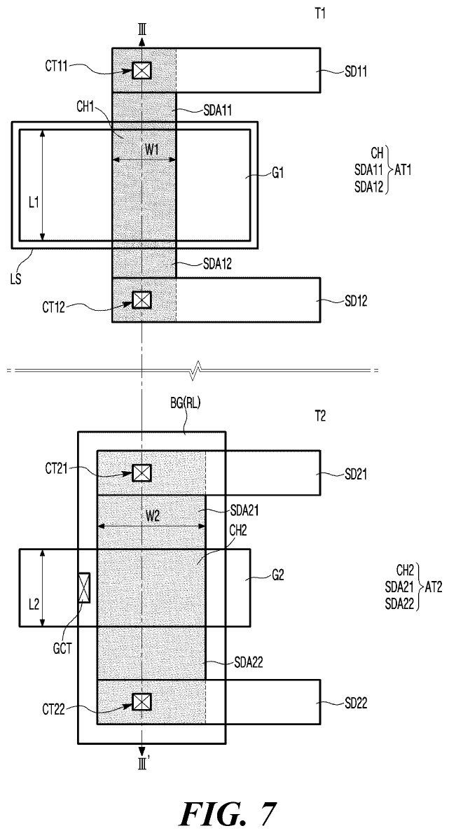

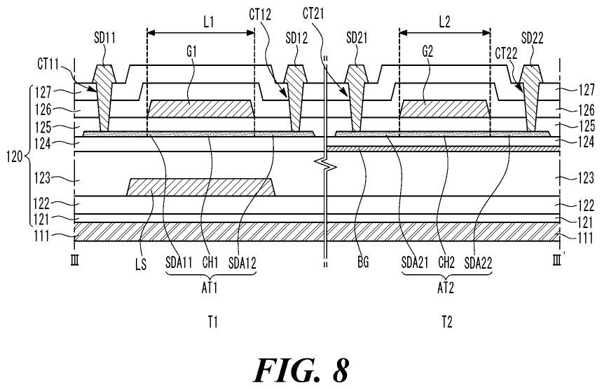

FIG. 7 is a plan view showing the first and second transistors of FIG. 2 or 6, and FIG. 8 is a cross-sectional view taken along line III-III′ of FIG. 7.

As shown in FIGS. 7 and 8, the first transistor T1 may be disposed on the substrate 111 and include a first oxide semiconductor layer AT1 including a first channel CH1, and a first upper gate electrode G1 disposed above the first oxide semiconductor layer AT1 to overlap the first channel CH1.

The first oxide semiconductor layer AT1 of the first transistor T1 may include first and second source-drain regions SDA11 and SDA12 on both sides of the first channel CH1.

In addition, the first transistor T1 may include source-drain electrodes SD11 and SD12 connected to the first and second source-drain regions SDA11 and SDA12 through contact holes CT11 and CT12 provided in the fifth to seventh insulating films 125, 126, and 127.

A light-shielding metal LS that overlaps at least the first channel CH1 may be disposed below the first oxide semiconductor layer AT1 in order to prevent light from being transmitted from below the substrate 111 to the first oxide semiconductor layer AT1. The light-shielding metal LS may have a larger area than the first upper gate electrode G1, but is not limited thereto.

The light-shielding metal LS may be formed of a conductive metal material.

Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The light-shielding metal LS may have a multilayer film structure including at least two conductive metal materials.

In some cases, the light-shielding metal LS may be connected to the first upper gate electrode G1 located above the first oxide semiconductor layer AT1 so as to secure a high current or control the threshold voltage.

The second transistor T2 may be disposed on the substrate 111 to be spaced apart from the first transistor T1.

The second transistor T2 includes a second oxide semiconductor layer AT2 having a second channel CH2 in the center and a first source-drain region SDA21 and a second source-drain region SDA22 on both sides of the second channel CH2, a second upper gate electrode G2 disposed above the second oxide semiconductor layer AT2 to overlap the second channel CH2 with the fifth insulating film 125 functioning as a gate insulating film interposed therebetween, and a lower gate electrode BG disposed below the second oxide semiconductor layer AT2 to overlap at least the second channel CH2 and connected to the upper gate electrode G2 outside the second oxide semiconductor layer AT2.

The first and second oxide semiconductor layers AT1 and AT2 of the first and second transistors T1 and T2 may be located in the same layer and formed in the same process. The display device according to one embodiment of the present disclosure defines the characteristics of the first and second transistors T1 and T2 by the sizes of the first and second channels CH1 and CH2 determined by overlapping areas between the first and second upper gate electrodes G1 and G2 and the first and second oxide semiconductor layers AT1 and AT2, but further includes the lower gate electrode BG below the second oxide semiconductor layer AT2 of the second transistor T2 that has a relatively high threshold voltage if a single gate electrode is applied, and selectively supplies a positive constant voltage to the lower gate electrode BG. Thereby, as shown in FIG. 5, the I-V curve may be shifted in the negative direction to lower the threshold voltage.

Therefore, the threshold voltage Vth of the second transistor T2 having a wide channel width and a short channel length may be adjusted similarly to the threshold voltage Vth of the first transistor T1 having a narrow channel width and a long channel length.

The voltage supply line may be, for example, the reference voltage line RL to which a rated voltage is applied. The voltage supply line connected to the lower gate electrode BG may be another power supply voltage line provided in the subpixel as long as a positive constant voltage may be applied thereto. A positive constant voltage may be applied to the reference voltage line RL to supply a gate voltage to the second transistor T2 through the lower gate electrode BG, thereby being capable of lowering the threshold voltage of the second transistor T2.

For example, the second transistor T2 may be a driving transistor. In addition to the second upper gate electrode G2 that supplies the gate voltage, the second transistor T2 may have the lower gate electrode BG connected to the reference voltage line RL, so that a gate voltage may be selectively supplied through the lower gate electrode BG, thereby being capable of shifting a high threshold voltage in the negative direction, and thus lowering a driving voltage, reducing power consumption, and having a stress reduction effect. This may improve the reliability of the driving transistor and secure robustness of the driving transistor so that the driving transistor does not deteriorate even after long-term driving.

The first transistor T1 may be a switching transistor that controls switching of the subpixel. Since the first transistor T1 is involved in high-speed operation, a channel size of the first transistor T1 may be smaller than that of the driving transistor. The length of the channel of the first transistor T1 may be longer than the width of the channel in consideration of an effective channel length. In some cases, the length of the channel of the first transistor T1 may be longer than the length of the channel of the second transistor T2, and the width of the channel of the first transistor T1 may be shorter than the width of the channel of the second transistor T2.

The first transistor (switching transistor) T1 and the second transistor (driving transistor) T2 require different widths and lengths of the channels due to different operating characteristics, and have threshold voltages with opposite tendencies. In the display device of one embodiment of the present disclosure, the second transistor T2 may have the second gate electrode to which a gate voltage is selectively supplied in addition to the first gate electrode, so that the threshold voltage of the second transistor may be adjusted to coincide with or be similar to the threshold voltage of the first transistor T1.

The lower gate electrode BG of the second transistor T2 may be connected to the voltage supply line and selectively receive a signal applied to the voltage supply line. The second transistor T2 may receive a positive constant voltage (positive bias voltage) through the voltage supply line whenever a gate signal is supplied to the second upper gate electrode G2. Alternatively, the supply cycle of the positive constant voltage to the voltage supply line may be different from the supply cycle of the gate signal. The adjustment of the threshold voltage Vth may vary depending on the magnitude and supply cycle of the positive constant voltage.

The substrate 111 and the insulating film 120 including the first to seventh insulating films 121, 122, 123, 124, 125, 126, and 127 has the same configurations as in the above-described embodiment and descriptions thereof will thus be omitted.

In the second transistor T2, the first source-drain electrode SD21 and the second source-drain electrode SD22 may be formed of a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). The first source-drain electrode SD1 and the second source-drain electrode SD2 may have a multilayer film structure including at least two conductive metal materials.

The first source-drain electrode SD21 and the second source-drain electrode SD22 of the second transistor T2 are connected to the first and second source-drain regions SDA21, SDA22 on both sides of the second oxide semiconductor layer AT2, respectively. The first source-drain electrode SD21 is connected to the first source-drain region SDA21 of the second oxide semiconductor layer AT2 through a first contact hole CT21 provided in the fifth to seventh insulating films 125, 126, and 127, and the second source-drain electrode SD22 is connected to the second source-drain region SDA22 of the second oxide semiconductor layer AT2 through a second contact hole CT22 provided in the fifth to seventh insulating films 125, 126, and 127.

As shown in FIGS. 7 and 8, the lower gate electrode BG may be connected to the overlapping second upper gate electrode G2 through a contact hole GCT provided in the fourth and fifth insulating films 124 and 125 at a portion protruding outwardly from the oxide semiconductor layer AT2. Here, the lower gate electrode BG may be integrated with the reference voltage line RL, and the second upper gate electrode G2 and the lower gate electrode BG may be at the same potential as the voltage supplied to the reference voltage line RL. Here, the voltage supplied to the power supply voltage line RL is a positive bias voltage, and the reference voltage value may vary depending on the magnitude of the threshold voltage to be adjusted.

The light-shielding metal LS of the first transistor T1 may be connected to the first upper gate electrode G1 or a separate ground signal may be applied to the light-shielding metal LS to further stabilize the characteristics of the first transistor T1.

The lower gate electrode BG of the second transistor T2 is located below the second oxide semiconductor layer AT2 and may also function to prevent light entering from below the substrate 111 from affecting the second oxide semiconductor layer AT2.

FIG. 8 shows an example in which the light-shielding metal LS of the first transistor T1 and the lower gate electrode BG of the second transistor T2 are located in different layers.

As shown in FIG. 8, if a vertical distance between the light-shielding metal LS and the first oxide semiconductor layer AT1 of the first transistor T1 is longer than a vertical distance between the lower gate electrode BG and the second oxide semiconductor layer AT2 of the second transistor T2, the first transistor T1 may further prevent occurrence of parasitic capacitance with the first oxide semiconductor layer AT depending on application of a voltage to the light-shielding metal LS, and may be driven independently of application of a voltage signal to the light-shielding metal LS.

For example, the reference voltage line RL may extend in the first direction from the lower gate electrode BG. The extending reference voltage line RL may be connected to a sensing transistor or a buffer transistor, etc., in the compensation circuit CC.

In the embodiments of the present disclosure, the lower gate electrode BG is further provided below the second oxide semiconductor layer AT2 in addition to the second upper gate electrode G2 provided above the second oxide semiconductor layer AT2, thereby enabling separate voltage compensation through the lower gate electrode BG, and thus being capable of selectively adjusting the threshold voltage of the second transistor T2.

An aspect of the embodiments of the present disclosure is to minimize the threshold voltage of each transistor by compensating the threshold voltage of a transistor having a high threshold voltage to be similar to the threshold voltage of a transistor having a low threshold voltage by supplying a reference voltage Vref even if the first and second transistors T1 and T2 with different channel widths and lengths have different characteristics.

Another aspect of the embodiments of the present disclosure is to enable reduction in stress and reduction in power consumption of transistors without affecting the characteristics of the transistors by selectively compensating the threshold voltages of the transistors.

Yet another aspect of the embodiments of the present disclosure is to implement transistors having different characteristics without any additional processes by adjusting overlapping areas between upper gate electrodes and oxide semiconductor layers of the transistors and changing the arrangement of a lower gate electrode or a light-shielding metal in the transistors including at least the oxide semiconductor layer. Accordingly, a display device that is capable of reducing greenhouse gases generated by additional manufacturing processes and implementing process optimization may be provided.

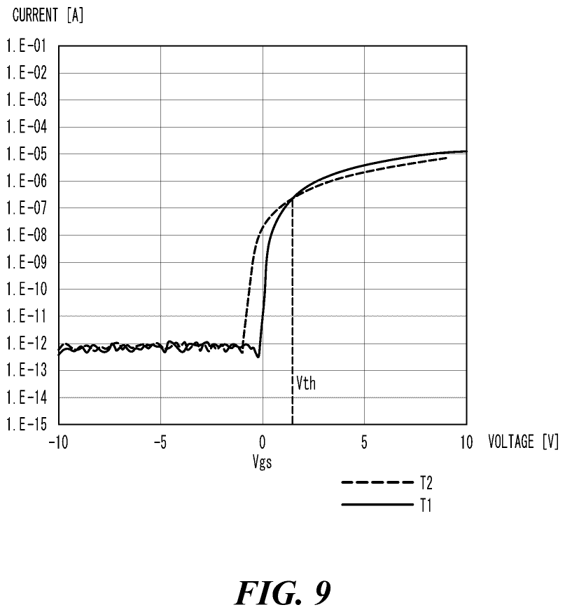

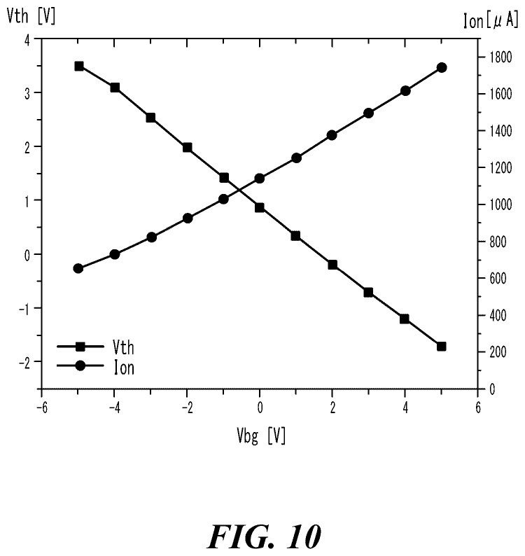

FIG. 9 is a graph showing I-V characteristics of the first and second transistors of the present disclosure, and FIG. 10 is a graph showing threshold voltage and on current changes according to a change in a voltage difference Vgs between a gate electrode and a source electrode of a transistor.

As shown in FIG. 9, when a positive bias voltage is applied through the lower gate electrode of the second transistor T2, the initial gate voltage of the second transistor T2 is relatively more shifted in the negative direction than the first transistor T1, so that the threshold voltages Vth of the first and second transistors T1 and T2 may coincide with each other or become nearly the same.

A gate on voltage of the first transistor T1 may be higher than a gate on voltage of the second transistor T2. A difference between the threshold voltages Vth of the first and second transistors T1 and T2 may be set to approximately 0.4 V or less, so that the stress on each of the first and second transistors T1 and T2 may be reduced and the power consumption of each of the first and second transistors T1 and T2 may be reduced.

FIG. 10 shows that, when the magnitude of the voltage applied to the lower gate electrode increases, the threshold voltage Vth gradually decreases and an on current value Ion gradually increases.

That is, it may be confirmed that the second transistor T2 to which the positive bias voltage is applied according to one embodiment of the present disclosure secures low threshold voltage Vth and high on current Ion characteristics.

For example, as shown in FIGS. 7 and 8, the first transistor T1 may be a switching transistor, and the second transistor T2 may be a driving transistor. In addition to the second upper gate electrode G2 that supplies a gate voltage, the second transistor T2 may further have the lower gate electrode BG connected to the reference voltage line RL, so that a gate voltage may be selectively supplied through the lower gate electrode BG, thereby shifting the high threshold voltage in the negative direction, and thus lowering the driving voltage and reducing power consumption and stress. This may improve the reliability of the driving transistor and secure robustness of the driving transistor so that the driving transistor does not deteriorate even after long-term driving.

The first transistor T1 may be a switching transistor that controls switching of the subpixel. Since the first transistor T1 is involved in high-speed operation, a channel size of the first transistor T1 may be smaller than that of the driving transistor. The length of the channel of the first transistor T1 may be longer than the width of the channel in consideration of an effective channel length. In some cases, the length of the channel of the first transistor T1 may be longer than the length of the channel of the second transistor T2, and the width of the channel of the first transistor T1 may be shorter than the width of the channel of the second transistor T2.

The first transistor (switching transistor) T1 and the second transistor (driving transistor) T2 require different widths and lengths of the channels due to different operating characteristics, and have threshold voltages with opposite tendencies. In the display device of one embodiment of the present disclosure, the second transistor T2 may have the second gate electrode to which a gate voltage is selectively supplied in addition to the first gate electrode, so that the threshold voltage of the second transistor T2 may be adjusted to coincide with or be similar to the threshold voltage of the first transistor T1.

Hereinafter, the display device having the light-emitting element together with the above-described first and second transistors will be described.

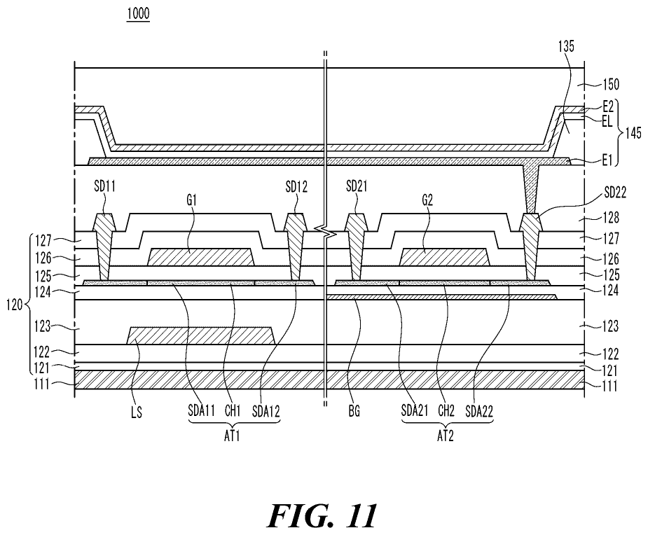

FIG. 11 is a cross-sectional view showing the display device according to one embodiment of the present disclosure.

As shown in FIG. 11, the display device 1000 according to one embodiment of the present disclosure may have the first transistor T1 and the second transistor T2 described above with reference to FIGS. 8 and 9 on the substrate 111, and may include a planarization film 128, a bank 135, light-emitting elements 145, and an encapsulation layer 150 that are disposed on the first transistor T1 and the second transistor T2.

The planarization film 128 may be disposed on the first transistor T1 and the second transistor T2 to protect the first transistor T1 and the second transistor T2 and alleviate steps caused by the first transistor T1 and the second transistor T2.

The planarization film 128 may be disposed between the structures or elements of the first transistor T1, the second transistor T2, wirings, and the light-emitting elements 145 to reduce parasitic capacitance occurring between the first transistor T1, the second transistor T2, wirings, and the light-emitting elements 145.

The planarization film 128 may be disposed on the insulating film 120 to provide a flat surface.

The planarization film 128 may include an organic material. The organic material may include at least one material selected from the group consisting of acrylic resins, phenolic resins, polyimide resins, unsaturated polyester resins, polyamide resins, benzocyclobutene, polyphenylene resins, and polyphenylene sulfide resins.

The planarization film 128 may be disposed as a composite stack of an inorganic insulating film and an organic insulating film. In addition to the insulating film 120 described above, various organic or inorganic materials may be further disposed between the substrate 111 and the planarization film 128.

The bank 135 is a pixel definition film that exposes a first electrode E1 of each subpixel SP. The bank 135 may include an opaque material (e.g., black) to prevent optical interference between adjacent subpixels SP. In this case, the bank 135 may include a light-blocking material formed of at least one of a color pigment, organic black, and carbon.

The light-emitting elements 145 are disposed on the planarization film 128 of the active area AA.

The light-emitting element 145 includes the first electrode E1, an emitting layer EL, and a second electrode E2. The light-emitting element 145 may be conductively connected to the second transistor T2 through the planarization film 128. The first electrode E1 of the light-emitting element 145 and the second source-drain electrode SD22 of the second transistor T2 are conductively connected to each other.

The first electrode E1 may function as an anode. The first electrode E1 may pass through the planarization film 128 and be connected to the second transistor T2.

The first electrode E1 may include a metal material having high reflectivity. For example, the first electrode E1 may be formed as a multilayer structure, such as a stacked structure (Ti/Al/Ti) of aluminum (Al) and titanium (Ti), a stacked structure (ITO/Al/ITO) of aluminum (Al) and ITO, an APC (Ag/Pd/Cu) alloy, a stacked structure (ITO/APC/ITO) of an APC alloy and ITO, or a stacked structure (Ag/MoTI) of silver (Ag) and a molybdenum/titanium alloy, or may include a single layer structure formed of one material selected from silver (Ag), aluminum (Al), molybdenum (Mo), gold (Au), magnesium (Mg), calcium (Ca), and barium (Ba), or an alloy of two or more materials selected therefrom. The first electrode E1 may be referred to as a reflective electrode.

The emission layer EL is provided on the first electrode E1. The emission layer EL may include a hole injection layer, a hole transport layer, an organic emission layer, an electron transport layer, and an electron injection layer.

When a voltage is applied to the first electrode E1 and the second electrode E2, holes move to the organic emission layer through the hole injection layer and the hole transport layer, and electrons move to the organic emission layer through the electron injection layer and the electron transport layer, respectively, the holes and the electrons recombine with each other in the organic emission layer to form excitons, and the excitons drop in energy from the excited state to the ground state to emit light.

The emission layer EL may be formed as a red emission layer that emits red light, a green emission layer that emits green light, and a blue emission layer that emits blue light. The red emission layer, the green emission layer, and the blue emission layer may be disposed for each subpixel SP on the first electrode E1.

The red emission layer may be arranged in a patterned manner in red subpixels, the green emission layer may be arranged in a patterned manner in green subpixels, and the blue emission layer may be arranged in a patterned manner in blue subpixels, but the red, green, and blue emission layers are not limited thereto, and at least two or more organic emission layers among the red emission layer, the green emission layer, and the blue emission layer may be stacked and disposed in one subpixel SP.

The emission layer EL may be a white emission layer that emits white light. In this case, the emission layer EL may be a common layer obtained by disposing one or more layers in common in the subpixels SP, not in a patterned manner.

As described above, the emission layer EL may be disposed in a tandem structure of two or more stacks. At this time, each light-emitting element 145 may include a charge generation layer disposed between the respective stacks. The charge generation layer may be a common layer disposed on the entire surface of the active area AA.

The second electrode E2 is provided on the emission layer EL. The second electrode E2 may function as a cathode.

The second electrode E2 may be disposed not only in the emission area of each subpixel SP but also throughout the entire surface of the active area AA, but is not limited thereto.

The second electrode E2 may be a common layer that is commonly disposed on the subpixels SP and applies the same voltage. For this purpose, the second electrode E2 may be disposed to extend from the active area AA to a part of the non-active area NA.

The second electrode E2 may be a transmissive electrode. The second electrode E2 may include a transparent metal material (i.e., a transparent conductive oxide material (TCO)), such as ITO or IZO that may transmit light, or a semi-transmissive metal material (i.e., a semi-transmissive conductive material), such as magnesium (Mg), silver (Ag), or an alloy of magnesium (Mg) and silver (Ag). When the second electrode E2 is a semi-transmissive conductive material, light extraction efficiency may be increased by micro-cavities.

The top-emission type has been described above as an example of the light-emitting element 145. However, the light-emitting element 145 of the present disclosure is not limited thereto, and may be a bottom-emission type in which light emitted from the emission layer EL is emitted toward the substrate 111. In this case, the first electrode E1 may be formed of a transparent or translucent electrode material, and the second electrode E2 may be formed of a reflective electrode material.

The encapsulation layer 150 is disposed on the light-emitting elements 145. The encapsulation layer 150 may cover the active area AA and the non-active area NA to prevent oxygen or moisture from penetrating into the light-emitting elements 145. If necessary, other layers, such as a capping layer, may be interposed between the encapsulation layer 150 and the second electrode E2.

The encapsulation layer 150 may include a plurality of layers. The encapsulation layer 150 may be formed as a structure in which an inorganic film including an inorganic insulating material and an organic film including an organic insulating material are alternately stacked. For example, the inorganic insulating material may include at least one material, such as silicon oxide, silicon nitride, and/or silicon oxynitride.

The organic insulating material may include at least one material selected from the group consisting of polyethylene terephthalate, polyethylene naphthalate, polycarbonate, polyimide, polyethylene sulfonate, polyoxymethylene, polyarylate, and hexamethyldisiloxane.

In the display device 1000, a voltage may be selectively supplied to the second transistor T2 through the power supply voltage line connected to the lower gate electrode BG, thereby being capable of lowering the threshold voltage, and reducing stress applied to the second transistor T2 due to the lowered threshold voltage. In addition, there is an effect of reducing power consumption when the second transistor T2 is driven.

In the display device 1000 of the present disclosure, when different first and second transistors T1 and T2 having different I-V curves are provided, the second transistor T2 with a smaller slope of the I-V curve has the lower gate electrode BG and the reference voltage line RL is provided to be connected to the lower gate electrode BG, so that the threshold voltage of the second transistor T2 may be adjusted to be similar to that of the first transistor T1 by selectively applying a positive bias voltage through the reference voltage line RL.

The first transistor T1 may be a switching transistor, and the second transistor T2 may be a driving transistor. In addition to the second upper gate electrode G2 that supplies a gate voltage, the second transistor T2 may be separately provided with the lower gate electrode BG connected to the reference voltage line RL, so that a gate voltage may be selectively supplied through the lower gate electrode BG, thereby shifting the high threshold voltage in the negative direction, and thus lowering a driving voltage and reducing power consumption and stress. This may improve the reliability of the driving transistor and secure robustness of the driving transistor so that the driving transistor does not deteriorate even after long-term driving.

The first transistor T1 may be a switching transistor that controls switching of the subpixel. Since the first transistor T1 is involved in high-speed operation, the channel size of the first transistor T1 may be smaller than that of the driving transistor. The length of the channel of the first transistor T1 may be longer than the width of the channel in consideration of an effective channel length. In some cases, the length of the channel of the first transistor T1 may be longer than the length of the channel of the second transistor T2, and the width of the channel of the first transistor T1 may be shorter than the width of the channel of the second transistor T2.

The first transistor (switching transistor) and the second transistor (driving transistor) require different widths and lengths of the channels due to different operating characteristics, and have threshold voltages with opposite tendencies. In the display device of one embodiment of the present disclosure, the second transistor may have the second gate electrode to which a gate voltage is selectively supplied in addition to the first gate electrode, so that the threshold voltage of the second transistor may be adjusted to coincide with or be similar to the threshold voltage of the first transistor.

In the display device according to one embodiment of the present disclosure, in the second transistor (driving transistor), a positive constant voltage may be selectively supplied through the voltage supply line, and the threshold voltage of the second transistor may be shifted to coincide with or be similar to the threshold voltage of the first transistor (switching transistor) different from the second transistor. Thereby, the threshold voltages of the switching transistor and the driving transistor having different operating characteristics and functions may match each other by the voltage supplied to the voltage supply line.

The display device of the present disclosure may implement transistors having different characteristics without any additional processes by adjusting overlapping areas between upper gate electrodes and oxide semiconductor layers of the transistors and changing the arrangement of a lower gate electrode or a light-shielding metal in the transistors including at least the oxide semiconductor layer.

The display device of the present disclosure may implement transistors having different characteristics without any additional processes, thereby being capable of reducing greenhouse gases generated by additional manufacturing processes, implementing process optimization, and achieving environmental/social/governance effects with sustainability.

Currently, development of transistors including an oxide semiconductor for displays is focused on developing robust devices that do not deteriorate even after long-term operation.

Oxide semiconductor transistors are widely used as switching elements for low-refresh rate driving due to low off current characteristics. In addition, application of the oxide semiconductor transistors as driving transistors for low-power displays due to fast saturation characteristics is also being studied.

Since switching transistors and driving transistors require different driving characteristics, the channel widths and channel lengths of the semiconductor layers of the switching and driving transistors are formed differently, and thus the switching and driving transistors have different threshold voltages.

It is necessary to develop elements having a robust structure that have a margin to satisfy the operating requirements of various elements. A transistor of the present disclosure may be additionally provided with wiring that applies a positive bias voltage to the lower end of an active layer when implemented as a driving transistor, so that the threshold voltage of the driving transistor may be shifted in the negative direction, thereby reducing element stress and improving stability.

The driving transistor may express gradation only when a slope indicating a change in driving current depending on a change in gate voltage in the I-V curve is gentle. The transistor of the present disclosure may shift the threshold voltage, which has been shifted in the positive direction, again in the negative direction by supplying a voltage through an additional lower gate electrode even if the slope of the I-V curve is small, thereby being capable of changing the threshold voltage of the driving transistor to close to 0 V.

The driving transistor with the lowered threshold voltage may be driven at a lower voltage, and the level of stress applied to the driving transistor may be reduced, thereby suppressing element deterioration. In addition, an effect of reducing power consumption may also be expected because the driving voltage is lowered.

In addition, the transistor according to one embodiment of the present disclosure may selectively control the threshold voltage by applying a back bias voltage to the lower end of the oxide semiconductor layer.

The transistor including an oxide semiconductor may increase a process margin by controlling a threshold voltage, and may reduce stress applied to the transistor. So the device including the transistor including an oxide semiconductor may increase reliability. In addition, there is an effect of reducing power consumption when the transistor is driven.

A transistor according to one embodiment of the present disclosure may comprise an oxide semiconductor layer having a first source-drain region, a channel, and a second source-drain region in a first direction, an upper gate electrode disposed above the oxide semiconductor layer and configured to overlap the channel with a gate insulating film interposed therebetween, a lower gate electrode disposed below the oxide semiconductor layer, configured to overlap at least the channel, and connected to the upper gate electrode at a position configured to extend outwardly from the oxide semiconductor layer, a first source-drain electrode and a second source-drain electrode connected to the first and second source-drain regions, respectively and a voltage supply line connected to the lower gate electrode and configured such that a positive constant voltage is supplied to the voltage supply line.

In a transistor according to one embodiment of the present disclosure, the voltage supply line may be integrated with the lower gate electrode.

In a transistor according to one embodiment of the present disclosure, the voltage supply line may be a reference voltage line.

In a transistor according to one embodiment of the present disclosure, the positive constant voltage may be selectively supplied through the voltage supply line. A threshold voltage of the transistor used as a driving transistor may match a threshold voltage of a switching transistor. In other words, a threshold voltage of the transistor used as a driving transistor may be either equal to or substantially equal to a threshold voltage of a switching transistor.

In a transistor according to one embodiment of the present disclosure, at least one interlayer insulating film may be provided between the oxide semiconductor layer and the lower gate electrode. The upper gate electrode and the lower gate electrode may be connected to each other by a contact hole configured to penetrate the gate insulating film and the at least one interlayer insulating film. The contact hole may be spaced apart from the oxide semiconductor layer.

In a transistor according to one embodiment of the present disclosure, one of the first source-drain electrode and the second source-drain electrode may be connected to one electrode of a light-emitting element so that a current through the transistor is supplied to the light-emitting element.

A display device according to one embodiment of the present disclosure may comprise a first transistor disposed on a substrate, a second transistor disposed on the substrate to be spaced apart from the first transistor and a voltage supply line. The first transistor may comprise a first oxide semiconductor layer comprising a first channel, and a first upper gate electrode configured to overlap the first channel on the first oxide semiconductor layer. The second transistor may comprise a second oxide semiconductor layer having a second channel at a center and a first source-drain region and a second source-drain region at both sides of the second channel, a second upper gate electrode disposed above the second oxide semiconductor layer and configured to overlap the second channel with a gate insulating film interposed therebetween, and a lower gate electrode disposed below the second oxide semiconductor layer, configured to overlap at least the second channel, and connected to the second upper gate electrode at a position configured to extend outwardly from the second oxide semiconductor layer. The voltage supply line may be connected to the lower gate electrode.

In a display device according to one embodiment of the present disclosure, a positive constant voltage may be supplied to the voltage supply line.

In a display device according to one embodiment of the present disclosure, the first transistor may be a switching transistor and the second transistor may be a driving transistor. A threshold voltage of the first transistor and a threshold voltage of the second transistor may match each other by the voltage supplied to the voltage supply line. In other words, a threshold voltage of the first transistor and a threshold voltage of the second transistor may be either equal to or substantially equal to each other by the voltage supplied to the voltage supply line.

In a display device according to one embodiment of the present disclosure, the voltage supply line may be integrated with the lower gate electrode of the second transistor.

In a display device according to one embodiment of the present disclosure, the voltage supply line may be a reference voltage line.

In a display device according to one embodiment of the present disclosure, the voltage supply line may selectively supply a positive constant voltage to the lower gate electrode.

In a display device according to one embodiment of the present disclosure, at least one interlayer insulating film may be provided between the second oxide semiconductor layer and the lower gate electrode. The second upper gate electrode and the lower gate electrode may be connected to each other by a contact hole configured to penetrate the gate insulating film and the at least one interlayer insulating film. The contact hole may be spaced apart from the second oxide semiconductor layer.

In a display device according to one embodiment of the present disclosure, a width of a second channel of the second transistor may be longer than a width of a first channel of the first transistor.

In a display device according to one embodiment of the present disclosure, the first oxide semiconductor layer and the second oxide semiconductor layer may be located at a same layer.

In a display device according to one embodiment of the present disclosure, the first source-drain region may be connected to a first source-drain electrode, the second source-drain region may be connected to a second source-drain electrode. One of the first source-drain electrode and the second source-drain electrode may be connected to a light-emitting element.

In a display device according to one embodiment of the present disclosure, the first transistor may be a switching transistor and the second transistor may be a driving transistor. The first channel and the second channel may be different in at least one of a width and a length. A gate on voltage of the first transistor may be higher than a gate on voltage of the second transistor.

Threshold voltages of the first transistor and the second transistor may be the same or have a difference of 0.4 V or less.

A display device according to one embodiment of the present disclosure may further comprise a light-shielding metal located to overlap the first channel below the first oxide semiconductor layer and disposed at a different layer from the lower gate electrode.

In a display device according to one embodiment of the present disclosure, the first transistor may be a switching transistor and the second transistor may be a driving transistor; and the first transistor and the second transistor may be provided at each of a plurality of subpixels provided on the substrate.

In a display device according to one embodiment of the present disclosure, the first transistor may be a switching transistor and the second transistor may be a driving transistor. The second transistor may be provided at each of a plurality of subpixels provided on the substrate. The first transistor may be provided at a non-active area configured to surround the plurality of subpixels.

A display device according to one embodiment of the present disclosure may further comprise a third transistor comprising a semiconductor layer comprising a third channel having a different width from the second channel at each of the plurality of subpixels.

As is apparent from the above description, a driving transistor and a display device including the same of the present disclosure have the following effects.

The transistor of the present disclosure has a lower gate electrode further provided below a semiconductor layer in addition to an upper gate electrode provided above the upper side of the semiconductor layer, so that separate voltage compensation is possible through the lower gate electrode.

The transistor of the present disclosure has a characteristic that the slope of a I-V curve representing a current for a voltage changing from the off state to the on state for gradation expression is small, but a positive bias voltage may be selectively applied through the lower gate electrode, thereby being capable of lowering a threshold voltage.

The transistor of the present disclosure may lower the threshold voltage by selective voltage supply, and may reduce stress applied to the transistor due to the lowered threshold voltage. In addition, there is an effect of reducing power consumption when the transistor is driven.

The display device of the present disclosure may, among a driving transistor and a switching transistor having different slopes of I-V curves thereof, supply a positive bias voltage through a voltage supply line connected to a lower gate electrode of the driving transistor to shift the threshold voltage of the driving transistor in the negative direction so as to match the threshold voltage of the switching transistor. This allows the threshold voltages of the switching transistor and the driving transistor having different operating characteristics and functions to match each other.

The display device of the present disclosure may adjust the threshold voltages of the driving transistor and the switching transistor to be similar to each other. This adjustment of the threshold voltages may be selectively performed, so that even if a difference between the threshold voltages of the switching transistor and the driving transistor changes over time depending on the driving, this state may be adjusted to the initial state.

The display device of the present disclosure may implement transistors having different characteristics without any additional processes by adjusting overlapping areas between upper gate electrodes and oxide semiconductor layers of the transistors and changing the arrangement of a lower gate electrode or a light-shielding metal in the transistors including at least the oxide semiconductor layer.

The display device of the present disclosure may implement transistors having different characteristics without any additional processes, thereby being capable of reducing greenhouse gases generated by additional manufacturing processes, implementing process optimization, and achieving environmental/social/governance effects with sustainability.

Through the above description, it should be apparent to those skilled in the art that various changes and modifications are possible without departing from the technical spirit of the present disclosure. Therefore, the technical scope of the present disclosure should not be limited to the above detailed description.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transistor comprising:
an oxide semiconductor layer having a first source-drain region, a channel, and a second source-drain region in a first direction;
a gate insulating film;
an upper gate electrode disposed above the oxide semiconductor layer, the upper gate electrode overlapping the channel with the gate insulating film interposed therebetween;
a lower gate electrode disposed below the oxide semiconductor layer, the lower gate electrode overlapping at least the channel, and connected to the upper gate electrode at a position configured to extend outwardly from the oxide semiconductor layer;
a first source-drain electrode and a second source-drain electrode connected to the first and second source-drain regions, respectively; and
a voltage supply line connected to the lower gate electrode and configured to receive a positive constant voltage.

2. The transistor according to claim 1, wherein:
the voltage supply line is integrated with the lower gate electrode.

3. The transistor according to claim 1, wherein the voltage supply line is a reference voltage line.

4. The transistor according to claim 1, wherein:
the positive constant voltage is selectively supplied through the voltage supply line; and
a threshold voltage of the transistor used as a driving transistor is either equal or substantially equal to a threshold voltage of a switching transistor.

5. The transistor according to claim 1, wherein:
at least one interlayer insulating film is provided between the oxide semiconductor layer and the lower gate electrode;
the upper gate electrode and the lower gate electrode are connected to each other by a contact hole configured to penetrate the gate insulating film and the at least one interlayer insulating film; and
the contact hole is spaced apart from the oxide semiconductor layer.

6. The transistor according to claim 1, wherein one of the first source-drain electrode and the second source-drain electrode is connected to one electrode of a light-emitting element so that a current through the transistor is supplied to the light-emitting element.

7. A display device comprising:
a first transistor disposed above a substrate and comprising a first oxide semiconductor layer comprising a first channel, and a first upper gate electrode configured to overlap the first channel on the first oxide semiconductor layer;
a second transistor disposed above the substrate to be spaced apart from the first transistor and comprising a second oxide semiconductor layer having a second channel positioned centrally between a first source-drain region and a second source-drain region, a second upper gate electrode disposed above the second oxide semiconductor layer and configured to overlap the second channel with a gate insulating film interposed therebetween, and a lower gate electrode disposed below the second oxide semiconductor layer, configured to overlap at least the second channel, and connected to the second upper gate electrode at a position configured to extend outwardly from the second oxide semiconductor layer; and
a voltage supply line connected to the lower gate electrode.

8. The display device according to claim 7, wherein a positive constant voltage is supplied to the voltage supply line.

9. The display device according to claim 7, wherein:
the first transistor is a switching transistor and the second transistor is a driving transistor; and
a threshold voltage of the first transistor and a threshold voltage of the second transistor are either equal to or substantially equal to each other by the voltage supplied to the voltage supply line.

10. The display device according to claim 7, wherein the voltage supply line is integrated with the lower gate electrode of the second transistor.

11. The display device according to claim 7, wherein the voltage supply line is a reference voltage line.

12. The display device according to claim 7, wherein:
the voltage supply line selectively supplies a positive constant voltage to the lower gate electrode.

13. The display device according to claim 7, wherein:
at least one interlayer insulating film is provided between the second oxide semiconductor layer and the lower gate electrode;
the second upper gate electrode and the lower gate electrode are connected to each other by a contact hole configured to penetrate the gate insulating film and the at least one interlayer insulating film; and
the contact hole is spaced apart from the second oxide semiconductor layer.

14. The display device according to claim 7, wherein a width of a second channel of the second transistor is longer than a width of a first channel of the first transistor.

15. The display device according to claim 7, wherein the first oxide semiconductor layer and the second oxide semiconductor layer are located at a same layer.

16. The display device according to claim 7, wherein:
the first source-drain region is connected to a first source-drain electrode;
the second source-drain region is connected to a second source-drain electrode; and
one of the first source-drain electrode and the second source-drain electrode is connected to a light-emitting element.

17. The display device according to claim 7, wherein:
the first transistor is a switching transistor and the second transistor is a driving transistor;
the first channel and the second channel are different in at least one of a width and a length;
a gate on voltage of the first transistor is higher than a gate on voltage of the second transistor; and
threshold voltages of the first transistor and the second transistor are the same or have a difference of 0.4 V or less.

18. The display device according to claim 7, further comprising a light-shielding metal located to overlap the first channel below the first oxide semiconductor layer and disposed at a different layer from the lower gate electrode.

19. The display device according to claim 18, wherein:
the first transistor is a switching transistor and the second transistor is a driving transistor; and
the first transistor and the second transistor are provided at each of a plurality of subpixels provided above the substrate.

20. The display device according to claim 18, wherein:
the first transistor is a switching transistor and the second transistor is a driving transistor;
the second transistor is provided at each of a plurality of subpixels provided above the substrate; and
the first transistor is provided at a non-active area configured to surround the plurality of subpixels.

21. The display device according to claim 20, further comprising a third transistor comprising a semiconductor layer comprising a third channel having a different width from the second channel at each of the plurality of subpixels.
